(19) United States
(12) Patent Application Publication
(10) Pub. No.: US 2012/0067962 A1
(43) Pub. Date: Mar. 22, 2012

(54) FOLDED SHEET ARTICLE AND METHOD OF MANUFACTURING THE SAME

(76) Inventor: George McDonald, Castel (GB)

(21) Appl. No.: 13/148,800

(22) PCT Filed: Feb. 8, 2010
(86) PCT No.: PCT/GB2010/050193

§ 371 Date: Nov. 14, 2011

(30) Foreign Application Priority Data
Feb. 10, 2009 (GB) 0902150.2

(51) Int. Cl. G06K 19/077; H05K 1/00

(52) U.S. Cl. 235/492; 174/254

(57) ABSTRACT

A folded sheet article comprising a sheet material having a first set of folds defining segments of the sheet material and an electrically conductive pattern on a segment of the sheet material that does not extend across a fold in an unfolded state.

### FIELD OF THE INVENTION

The present invention relates to folded sheet articles, whether in a folded or unfolded condition and to methods of manufacturing the same.

### BACKGROUND OF THE INVENTION

It is known from European Patent No. EP-B-0 288 472 to provide a folded sheet article comprising a first and second set of concertina folds, which sets of folds are transverse to one another. Provision of such folded sheets with stiff portions at segments of the sheet in the region of diagonally opposite corners of the sheet provides a means of easily unfolding and refolding the sheet material.

It is an aim of preferred embodiments of the present invention to overcome problems associated with the prior art, whether mentioned herein or otherwise.

### SUMMARY OF THE INVENTION

Generally, unless otherwise stated herein, the phrase “sheet material” is hereby defined as a material that takes folds at which is can be unfolded without the folds disappearing and refolded. It may be paper, or a paper-like material such as plastics sheet on which books are commonly printed, or may be very thin card or any other suitable material. It is conceivable that the sheet material may be stiff (e.g. card, semi-rigid paper or plastic) except at the folds, e.g. very thin stiff cards interconnected by paper, flexible plastic sheet or cloth, but this is deprecated as not allowing full realisation of the advantages of the invention.

The present invention in a first aspect provides a folded sheet article comprising a sheet material having a first set of folds defining segments of the sheet material and an electrically conductive pattern on a segment of the sheet material that does not extend across a fold in an unfolded state.

An electrically conductive pattern may be on several segments of the sheet, in which case at least one electrically conductive pattern does not extend across a fold and, preferably, none of the electrically conductive patterns extend across a fold.

Suitably, the electrically conductive pattern comprises a conductive printable ink.

The electrically conductive pattern may be a radio frequency identification tag.

In this specification the term radio frequency identification is abbreviated to RFID.

Suitably, the RFID tag is an active RFID tag. These can include semi-active RFID tags.

Alternatively, the RFID tag is a passive RFID tag. A passive RFID tag has no internal power source.

Suitably, the RFID tag is a chipless tag.

Suitably, the article comprises a stiff portion. Suitably, the first set of folds define segments in the sheet material and the stiff portion is located at a peripheral segment of the sheet material. Thus, if the sheet comprises a single row of segments, the stiff portion is suitably located at an end segment of the row.

Suitably, the stiff portion is located at or near a corner segment of the sheet.

Suitably, a first stiff portion and a second stiff portion are located at substantially diagonally opposite corners of the sheet.

Suitably, the stiff portion is attached (directly or indirectly) to the sheet material and the electrically conductive pattern is at least partly between the stiff portion and the sheet material. Suitably, the electrically conductive pattern is entirely between the stiff portion and the sheet material. Suitably, the stiff portion comprises a first layer and a second layer, wherein the electrically conductive pattern is at least partly between the first layer and the second layer. Suitably, the electrically conductive pattern is entirely between the first layer and the second layer. Suitably, the electrically conductive pattern is laminated between the first layer and the second layer.

The stiff portion may comprise one or more folds. Suitably, the one or more folds are parallel to an edge of the stiff portion. If the stiff portion comprises a plurality of folds, the plurality is suitably parallel to one another. Suitably the plurality of folds forms a spine when folded.

If the stiff portion is folded, each section of the folded stiff portion may be attached to the same or a different segment of the sheet. Alternatively, one section of the folded stiff portion may be attached to the sheet and the other section may be unattached to the sheet.

The same effect may be achieved by joining two separate stiff portions together along an edge thereof, thus replacing the fold line.

A stiff portion may be provided by a segment of the sheet that has been treated to make it stiffer than the rest of the sheet. For example, a segment may be soaked in a UV curable resin and then cured to provide the stiff portion.

If the folded sheet material comprises a stiff portion, the stiff portion suitably provides an outside cover of the sheet when the sheet is in a folded condition.

If a sheet in accordance with the present invention comprises two stiff portions, both of the stiff portions suitably provide a cover of the sheet when the sheet is in a folded condition.

Suitably, the stiff portions are made of card.

Generally, when the RFID tag is located in a stiff portion, an RFID tag is only in one of the stiff portions.

Suitably, the first set of folds is a set of concertina folds.

The folded sheet material may further comprise a second set of folds, which second set of folds are transverse to said first set of folds when said sheet is in a folded condition. Suitably, said second set of folds comprises a set of concertina folds.

Suitably, the first set of folds comprises an odd number of folds. Suitably, the second set of folds comprises an even number of folds.

Although one or both sets of folds may be non-parallel, e.g. convergent, and/or one or both of the stiff portions may, when the sheet is folded, not be outer portions, in a preferred embodiment the sheet is rectangular, the sets of folds being mutually perpendicular and parallel to the respective edges of the sheet, and the stiff portions being such as to be at the outside of the sheet when it has been folded by the first and second set of folds and being at least as large as the respective corner segments of the sheet.

Suitably, in the folded condition, there are at least 3 layers of folded sheet, preferably at least 8 layers and more preferably at least 16 layers.

According to the present invention in a second aspect, there is provided a method of manufacturing a folded sheet article according to the first aspect of the invention, the method comprising the step of providing a folded sheet article with an electrically conductive pattern that does not extend across a fold in an unfolded state.

The present invention in a third aspect provides a folded sheet article comprising a sheet material and a radio frequency identification tag, the sheet material having a first set of folds.

In this specification the term radio frequency identification is abbreviated to RFID.

Suitably, the RFID tag is an active RFID tag. These can include semi-active RFID tags.

Alternatively, the RFID tag is a passive RFID tag. A passive RFID tag has no internal power source.

Suitably, the RFID tag comprises a conductive printable ink.

Suitably, the RFID tag is a chipless tag.

Suitably, the article comprises a stiff portion. Suitably, the first set of folds define segments in the sheet material and the stiff portion is located at a peripheral segment of the sheet material. Thus, if the sheet comprises a single row of segments, the stiff portion is suitably located at an end segment of the row.

Suitably, the stiff portion is located at or near a corner segment of the sheet. Suitably, a first stiff portion and a second stiff portion are located at substantially diagonally opposite corners of the sheet.

Suitably, the stiff portion is attached (directly or indirectly) to the sheet material and the RFID tag is at least partly between the stiff portion and the sheet material. Suitably, the RFID tag is entirely between the stiff portion and the sheet material. Suitably, the stiff portion comprises a first layer and a second layer, wherein the RFID tag is at least partly between the first layer and the second layer. Suitably, the RFID tag is entirely between the first layer and the second layer. Suitably, the RFID tag is laminated between the first layer and the second layer.

The stiff portion may comprise one or more folds. Suitably, the one or more folds are parallel to an edge of the stiff portion. If the stiff portion comprises a plurality of folds, the plurality is suitably parallel to one another. Suitably the plurality of folds forms a spine when folded.

If the stiff portion is folded, each section of the folded stiff portion may be attached to the same or a different segment of the sheet. Alternatively, one section of the folded stiff portion may be attached to the sheet and the other section may be unattached to the sheet.

The same effect may be achieved by joining two separate stiff portions together along an edge thereof, thus replacing the fold line.

A stiff portion may be provided by a segment of the sheet that has been treated to make it stiffer than the rest of the sheet. For example, a segment may be soaked in a UV curable resin and then cured to provide the stiff portion.

If the folded sheet material comprises a stiff portion, the stiff portion suitably provides an outside cover of the sheet when the sheet is in a folded condition.

If a sheet in accordance with the present invention comprises two stiff portions, both of the stiff portions suitably provide a cover of the sheet when the sheet is in a folded condition.

Suitably, the stiff portions are made of card.

Generally, when the RFID tag is located in a stiff portion, an RFID tag is only in one of the stiff portions.

Suitably, the first set of folds is a set of concertina folds.

The folded sheet material may further comprise a second set of folds, which second set of folds are transverse to said first set of folds when said sheet is in a folded condition. Suitably, said second set of folds comprises a set of concertina folds.

Suitably, the first set of folds comprises an odd number of folds. Suitably, the second set of folds comprises an even number of folds.

Although one or both sets of folds may be non-parallel, e.g. convergent, and/or one or both of the stiff portions may, when the sheet is folded, not be outer portions, in a preferred embodiment the sheet is rectangular, the sets of folds being mutually perpendicular and parallel to the respective edges of the sheet, and the stiff portions being such as to be at the outside of the sheet when it has been folded by the first and second set of folds and being at least as large as the respective corner segments of the sheet.

Suitably, in the folded condition, there are at least 3 layers of folded sheet, preferably at least 8 layers and more preferably at least 16 layers.

Surprisingly, it has been found that an RFID tag incorporated in a folded sheet article as described above has a lower failure rate than would otherwise be the case. On further investigation, it significantly appears that this is because the additional layers provided by the folded sheets and/or the stiff portions provide increased resistance to the type of deformation of the RFID tag that tends to lead to failure. This is particularly the case in folded sheet articles that are pocket sized or credit card sized because they tend to be kept in a user's pocket where they are susceptible to day to day damage. It is believed that bending of an RFID tag about one axis tends not to cause a high rate of failure, whereas bending about two axes in contrast does significantly increase the failure rate.

According to the present invention in a fourth aspect, there is provided a method of manufacturing a folded sheet article according to the third aspect of the invention, the method comprising the step of providing a folded sheet article with a RFID tag.

### BRIEF DESCRIPTION OF THE DRAWINGS

The present invention will now be described, by way of example only, with reference to the following drawings, in which:

FIG. 1 shows a plan view of a first embodiment of a folded sheet article in accordance with the present invention in a folded condition.

FIG. 2 shows a plan view of the article of FIG. 1 in a partially unfolded condition.

FIG. 3 shows the article of FIGS. 1 and 2 in an unfolded condition.

FIG. 4A shows an exploded view of a corner of the article of FIGS. 1, 2 and 3.

FIG. 4B shows an exploded view of an alternative corner construction of the article of FIGS. 1, 2 and 3.

FIG. 5 shows a front plan view of a second embodiment of a folded sheet material in accordance with the present invention in a substantially unfolded condition.

FIG. 6 shows a rear plan view of the sheet of FIG. 5.

FIG. 7 shows a side view of a third embodiment of a folded sheet material in accordance with the present invention, in a folded condition.

FIG. 8 shows an enlarged view of a further embodiment of the present invention showing part of a sheet article.

### DETAILED DESCRIPTION OF PREFERRED EMBODIMENTS

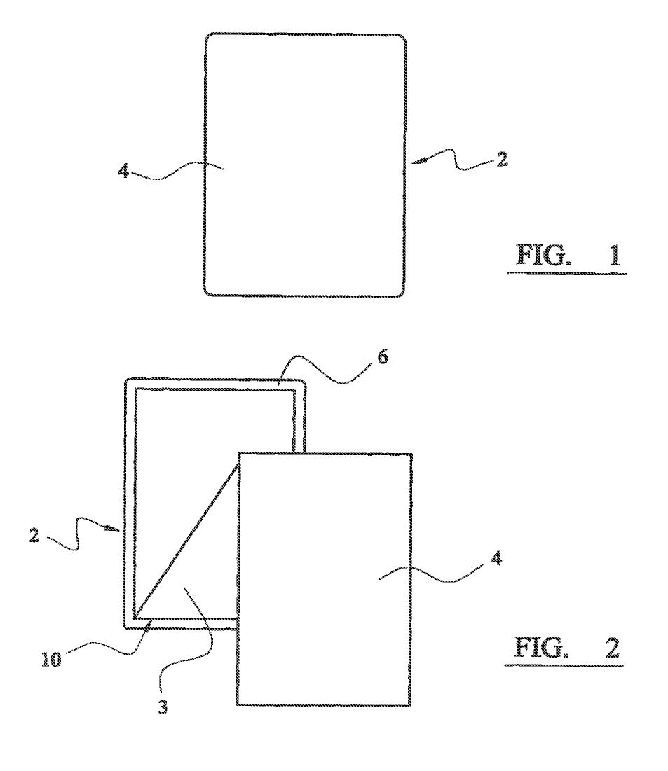

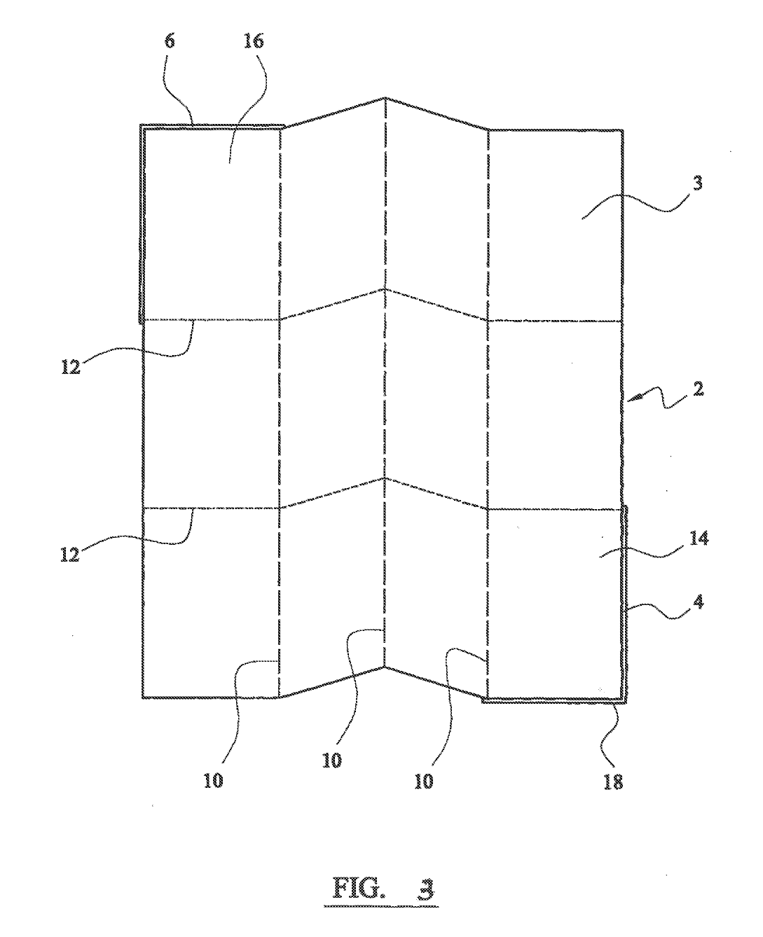

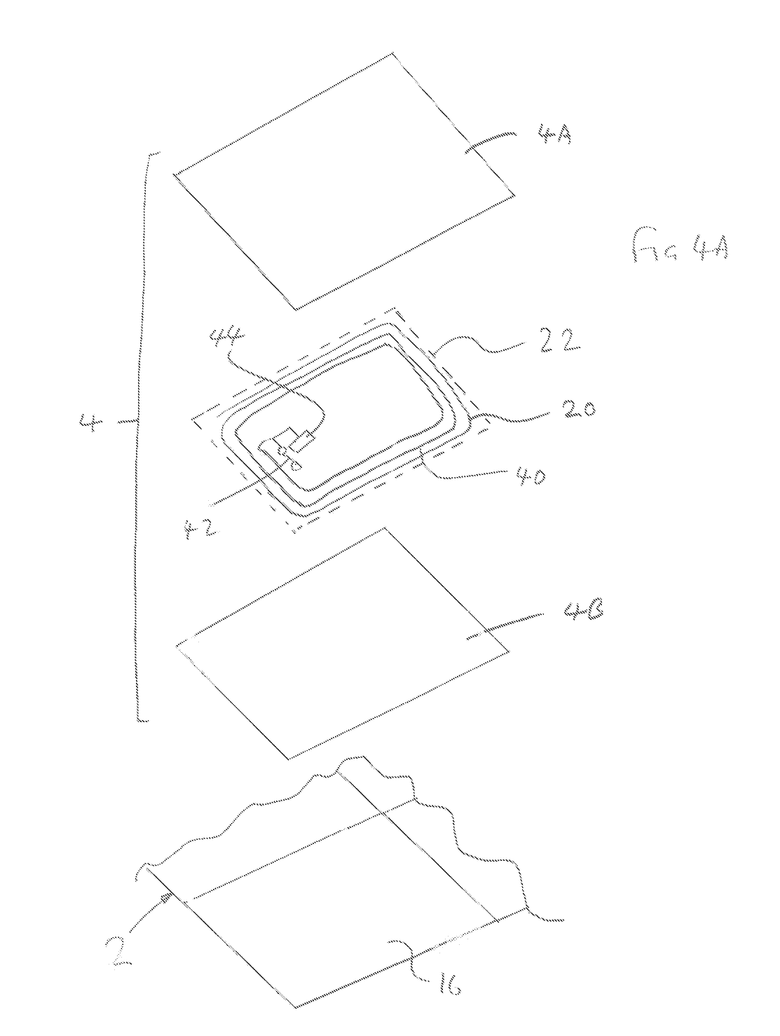

FIGS. 1, 2, 3 and 4 show a first embodiment of a folded sheet article 2 in accordance with the present invention.

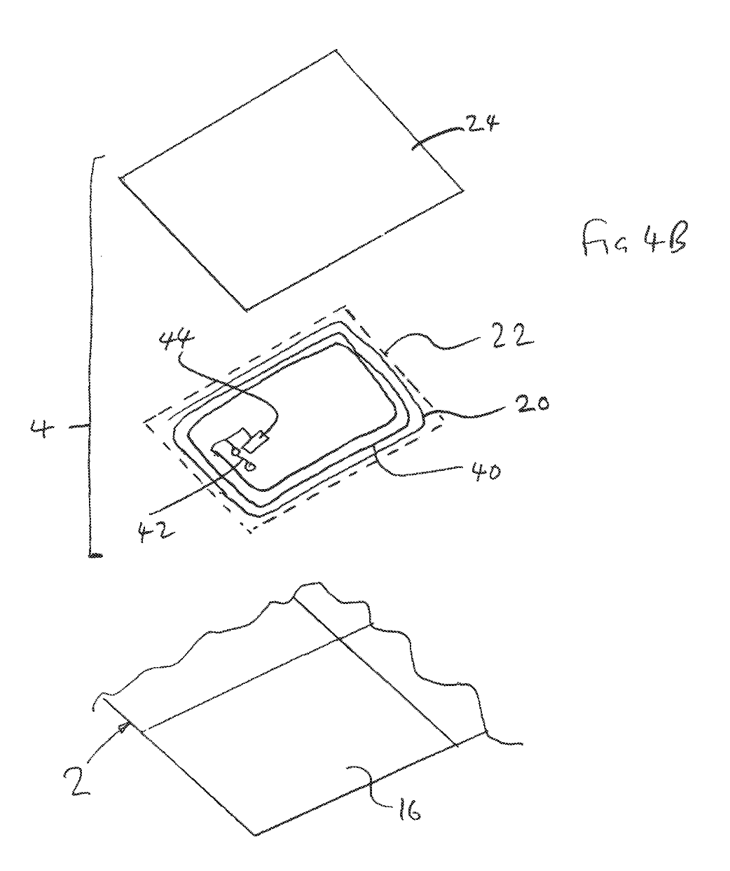

The folded sheet material 2 of FIGS. 1, 2, 3 and 4 comprises a first stiff portion 4, a second stiff portion 6, a first set of folds 10 (represented by broken lines in FIG. 4) and a second set of folds 12 (represented by dotted lines in FIG. 4). In this embodiment, folded sheet is of paper and the stiff portions are made of card that is relatively stiffer than the paper.

Both of the first set of folds 10 and the second set of folds 12 comprise a set of concertina folds. The folds define segments of the sheet.

The first stiff portion 4 is located at a corner segment 14 of the sheet 2. The second stiff portion 6 is located at a corner segment 16 of the sheet 2. The corner segments 14 and 16 are at diagonally opposite corner segments of the sheet.

With particular reference to FIG. 4A of the accompanying drawings, the first stiff portion 4 comprises a first layer 4A, a second layer 4B and a RFID tag 20 sandwiched between the first layer 4A and the second layer 4B.

The RFID tag 20 comprises an antenna portion 40, a battery portion 42 and a microprocessor portion 44. The antenna portion is made from an electrically conductive pattern.

The first layer 4A is glued to the second layer 4B by an adhesive. Alternatively, the first layer 4A can be laminated to the second layer 4B.

For ease of application, the RFID tag 20 can be applied to an intermediate carrier layer 22 which is then sandwiched between the first layer 4A and the second layer 4B. The RFID tag 20 can be printed onto such a layer 22 using a conductive ink.

The RFID tag 20 can be a passive tag or an active tag. In the illustrated embodiment it is an active tag because it includes an internal battery power source.

Advantageously, but not necessarily, the RFID tag can be printed using conductive ink onto one of the first or second layers 4A, 4B, or onto a carrier. Currently this requires the RFID tag 20 to be a chipless RFID tag but it is envisaged that RFID tags with chips using conductive ink may be possible in the future.

The stiff portion 4, carrying the RFID tag 20 is then adhered to the corner section 16 of the sheet.

FIG. 4B shows an alternative construction of the corner section of the article. In FIG. 4B, the first stiff portion 4 comprises a first layer 24 and a RFID tag 20. There is no second layer of the stiff portion in this embodiment.

The first layer 24 is glued or laminated to the corner section 16 of the sheet 2 with the RFID tag sandwiched therebetween.

For ease of application, the RFID tag 20 can be applied to an intermediate carrier layer 22. The RFID tag 20 can be printed onto such a layer 22 using a conductive ink. For ease of manufacture a side of the carrier layer 22 can be adhesive to assist in locating it between the stiff portion 24 and the sheet 2.

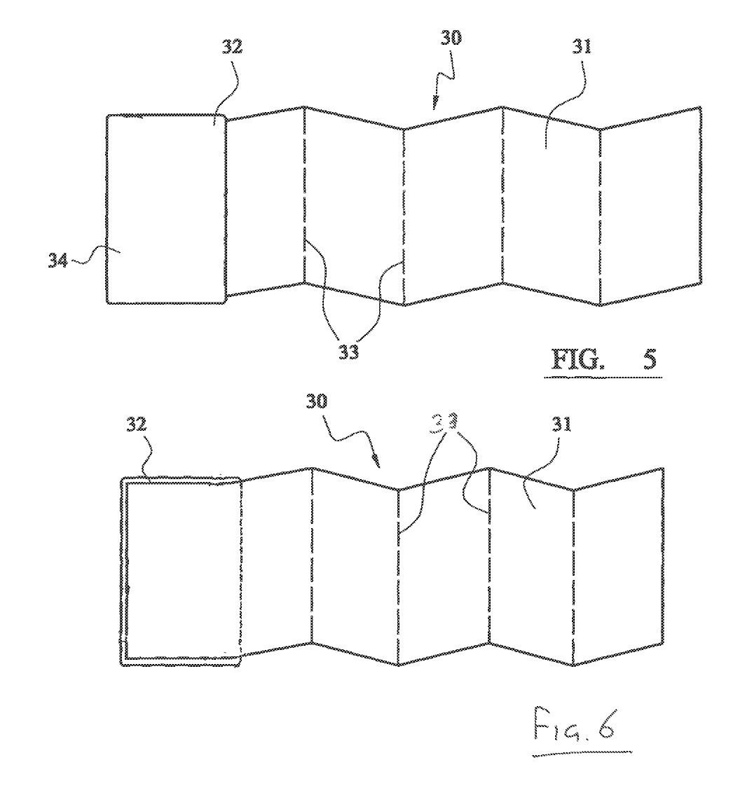

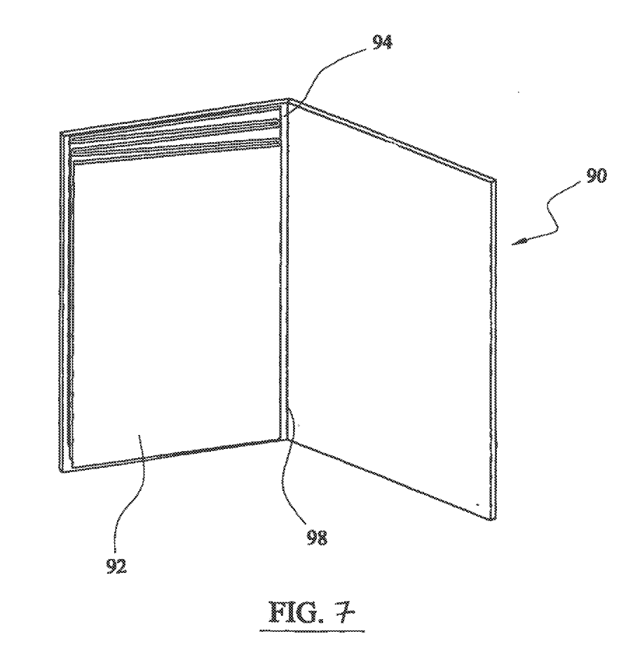

FIGS. 5 and 6 illustrate a second embodiment of the invention.

The folded sheet material 30 illustrated in FIGS. 5 and 6 comprises a first stiff portion 32 and a first set of folds 33 (represented by broken lines). The first stiff portion 32 contains (FIG. 4A) or overlies (FIG. 4B) the RFID tag 20 as described above.

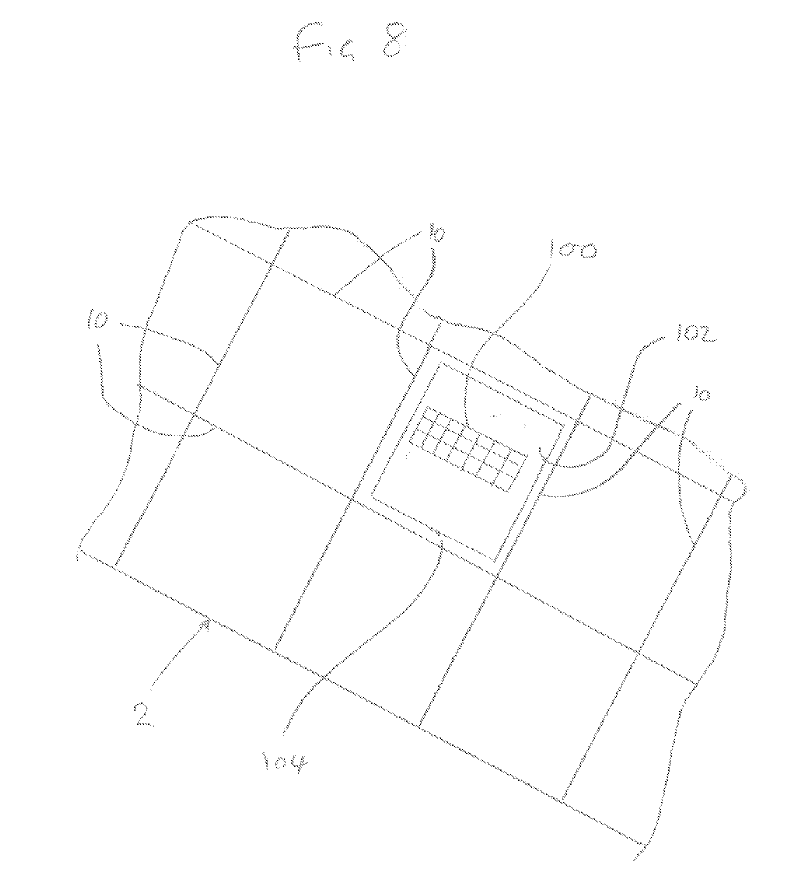

FIG. 7 illustrates a third embodiment of a folded sheet material 50 in accordance with the present invention.

The folded sheet material 90 comprises a folded sheet 92, comprising a first set of concertina folds and a stiff portion 94.

The stiff portion 94 comprises a fold 98.

In a folded condition, the stiff portion 94 folds about fold line 98 to provide a cover for the folded sheet 92.

The stiff portion 94 contains (FIG. 4A) or overlies (FIG. 4B) the RFID tag 20 as described above.

By keeping the electrically conductive pattern of the RFID tag 20 on a segment without crossing a fold line of the folded sheet, it avoids lines of weakness being formed in the electrically conductive pattern that can lead to failures of the FRID tag in use.

Folded sheet articles according to embodiments of the present invention can be used in a wide variety of applications, including, but not limited to the following:
Ski pass/piste map—in this case the RFID tag can act as a form of identification.
Railway (or other form of transport) ticket/map
Bus (or other form of transport) pass/timetable—a record can be kept of which RFID tags are associated with which timetables so that if a timetable is changed, the user of the old timetable can be alerted when they next try to use their pass.
Loyalty card/shop details
Pharmaceuticals identification/drugs information
City cards—museum tickets, theatre tickets

It will be appreciated that there are many other diverse applications to which embodiments of the present invention can be applied.

In an alternative embodiment of the present application shown in FIG. 8 of the accompanying drawings, which is a modification of the embodiment shown in FIG. 4, using the same reference numerals for corresponding parts. In FIG. 8 an electrically conductive pattern 100 is formed from a conductive ink on a carrier layer 102 which is applied to a non-corner segment 104 of the sheet, without the electrically conductive pattern crossing a fold line of the sheet.

Such an electrically conductive patter, without an RFID tag in this case, can be used for a variety of applications, such as augmented reality (“AR”) applications.

AR enables the real world to merge with virtual computer generated imagery, creating a mixed reality.

This is achieved by image registration of the optical information from print generated registration patterns, such as, but not limited to grids of black and white squares. (like a checkerboard not unlike a barcode).

Once the registration pattern is detected by a camera this is automatically displayed as a 3D image generated from these printed patterns.

Consequently feature detection is crucially depended on corner and edge detection, thresholding and other image processing methods.

One of the key difficulties in developing AR applications has been the problem of image disruption and distortion, due to the degradation of the target image caused by crease lines corrupting the pattern. Anyone who has experienced delays at supermarket checkout counters because of creases in packaging barcodes will be familiar with the problem.

To solve this problem, it has been found that providing the target AR image pattern within the fold lines i.e. in one segment of a folded sheet preserves the virginity of the pattern and significantly increases the detection rate. This is achieved by ensuring the AR patterns are more stable and as clear and uncontaminated as possible, providing the highest possible performance recognition by a camera.

This in turn opens up the easy development of a wide range of commercial AR applications. This is achieved by making the user experience interactive e.g. user guides, gallery guides, product information, etc. by holding the folded sheet article against a webcam which shows a 3D image and enables the user to interact with the product and select personalized variations if desired.

If desired electrically conductive patterns can be applied to a plurality of segments of the sheet, in which case the article falls within the scope of the present claims provided there is one electrically conductive pattern that does not cross a fold line, but it is preferable that a plurality of such electrically conductive patterns do not cross fold lines of the sheet, and more preferable that none of such electrically conductive patterns cross a fold line.

The reader's attention is directed to all papers and documents which are filed concurrently with or previous to this specification in connection with this application and which are open to public inspection with this specification, and the contents of all such papers and documents are incorporated herein by reference.

All of the features disclosed in this specification (including any accompanying claims, abstract and drawings), and/or all of the steps of any method or process so disclosed, may be combined in any combination, except combinations where at least some of such features and/or steps are mutually exclusive.

Each feature disclosed in this specification (including any accompanying claims, abstract and drawings), may be replaced by alternative features serving the same, equivalent or similar purpose, unless expressly stated otherwise. Thus, unless expressly stated otherwise, each feature disclosed is one example only of a generic series of equivalent or similar features.

The invention is not restricted to the details of the foregoing embodiment(s). The invention extend to any novel one, or any novel combination, of the features disclosed in this specification (including any accompanying claims, abstract and drawings), or to any novel one, or any novel combination, of the steps of any method or process so disclosed.

1. A folded sheet article comprising a sheet material having a first set of folds defining segments of the sheet material and an electrically conductive pattern or a print generated registration pattern on a segment of the sheet material that does not extend across a fold in an unfolded state.

2. The folded sheet article of claim 1, wherein an electrically conductive pattern is on several segments of the sheet, in which case at least one electrically conductive pattern does not extend across a fold.

3. The folded sheet article of claim 2, wherein none of the electrically conductive patterns extend across a fold.

4. The folded sheet article of claim 1, wherein the electrically conductive pattern comprises a conductive printable ink.

5. The folded sheet article of claim 1, wherein the electrically conductive pattern is a radio frequency identification tag.

6-8. (canceled)

9. The folded sheet article of claim 1, wherein the article comprises a stiff portion.

10. The folded sheet article of claim 9, wherein a first set of folds define segments in the sheet material and the stiff portion is located at a peripheral segment of the sheet material.

11. The folded sheet article of claim 9, wherein the stiff portion is located at or near a corner segment of the sheet.

12. The folded sheet article of claim 9, wherein a first stiff portion and a second stiff portion are located at substantially diagonally opposite corners of the sheet.

13. The folded sheet article of claim 9, wherein the stiff portion is attached to the sheet material and the electrically conductive pattern is at least partly between the stiff portion and the sheet material.

14. The folded sheet article of claim 13, wherein the electrically conductive pattern is entirely between the stiff portion and the sheet material.

15. The folded sheet article of claim 13 or claim 11, wherein the stiff portion comprises a first layer and a second layer, wherein the electrically conductive pattern is at least partly between the first layer and the second layer.

16. The folded sheet article of claim 15, wherein the electrically conductive pattern is entirely between the first layer and the second layer.

17. The folded sheet article of claim 15, wherein the electrically conductive pattern is laminated between the first layer and the second layer.

18-23. (canceled)

24. The folded sheet article of claim 9, wherein a radio frequency identification tag is located in the stiff portion, and the radio frequency identification tag is in only one stiff portion.

25-30. (canceled)

31. A method of manufacturing a folded sheet article according to claim 1, the method comprising the step of providing a folded sheet article with an electrically conductive pattern that does not extend across a fold in an unfolded state.

32. A folded sheet article comprising a sheet material and a radio frequency identification tag, the sheet material having a first set of folds.

33-46. (canceled)

47. A method of manufacturing the folded sheet article according to claim 32, the method comprising the step of providing a folded sheet article with a radio frequency identification tag.
